(19) United States
(12) Patent Application Publication
(10) Pub. No.: US 2025/0369844 A1
(43) Pub. Date: Dec. 4, 2025

(54) TESTING DEVICE FOR DISPLAY APPARATUS AND METHOD OF MANUFACTURING DISPLAY APPARATUS

(71) Applicant: Samsung Display Co., LTD., Yongin-si (KR)

(72) Inventors: Ohjune KWON, Yongin-si (KR); Kwanhyuck YOON, Yongin-si (KR)

(21) Appl. No.: 19/049,308

(22) Filed: Feb. 10, 2025

(30) Foreign Application Priority Data
May 29, 2024 (KR) 10-2024-0070356

(51) Int. Cl. G01N 3/06; G01N 3/20

(52) U.S. Cl. CPC G01N 3/068; G01N 3/20

(57) ABSTRACT

A testing device which is a stress measurement specimen for a display apparatus includes a specimen substrate and a reflector disposed on the specimen substrate. The specimen substrate includes a portion of a mother substrate used to manufacture the display apparatus. A method of manufacturing the display apparatus includes testing the display apparatus using the testing device.

This application claims priority to Korean Patent Application No. 10-2024-0070356, filed on May 29, 2024, and all the benefits accruing therefrom under 35 U.S.C. § 119, the content of which in its entirety is herein incorporated by reference.

### BACKGROUND

### 1. Field

Embodiments relate to a testing device for a display apparatus and a method of manufacturing a display apparatus, the method including testing a display apparatus by the testing device. The display apparatus may include light-emitting diodes, e.g., organic light-emitting diodes, as display elements.

### 2. Description of the Related Art

A display apparatus includes light-emitting diodes as display elements and may provide an image or video by the light-emitting diodes. A display apparatus may be manufactured by forming several layers on a substrate. Recently, display apparatuses may have flexible characteristics and thus some areas thereof may be bent. To manufacture a flexible display apparatus, a bendable flexible substrate may be disposed on a rigid glass substrate and several layers may be disposed on the flexible substrate. In this case, the glass substrate may be pulled in one or more directions to flatten a surface on which the flexible substrate and the several layers are to be disposed.

Thus, curvatures may occur on the stretched glass substrate, and such curvatures may similarly occur on the flexible substrate and the several layers thereon. In order to reduce or prevent the occurrence of such curvatures, devices and methods for measuring and evaluating stress formed within a glass substrate are desired.

### SUMMARY

In the related art, a silicon wafer specimen is disposed on a glass substrate, various layers are placed thereon, and then the stress in the silicon wafer specimen is measured. However, this method presents several issues. First, the physical properties of the silicon wafer specimen are different from those of the glass substrate, making it difficult to directly apply the stress measurement results to the glass substrate. Additionally, because the silicon wafer is placed on a glass substrate and various layers are placed thereon, a protrusion may occur due to the thickness of the silicon wafer, which may affect the stress measurement results.

Embodiments include a testing device for a display apparatus, i.e., a stress measurement specimen. Embodiments include a method of manufacturing a display apparatus.

Additional features will be set forth in part in the description which follows and, in part, will be apparent from the description, or may be learned by practice of the presented embodiments of the disclosure.

In an embodiment of the disclosure, a testing device for a display apparatus may include a specimen substrate and reflector disposed on the specimen substrate. The specimen substrate includes a portion of a mother substrate for manufacturing a display apparatus.

In an embodiment, the reflector may include a plurality of reflective patterns spaced apart from each other.

In an embodiment, the plurality of reflective patterns may include a plurality of concentric closed loops.

In an embodiment, a thickness of the specimen substrate may be less than a thickness of the mother substrate.

In an embodiment, the testing device for a display apparatus may further include a measurement mark above the specimen substrate.

In an embodiment, the testing device for a display apparatus may further include a protective film disposed on the reflector.

In an embodiment, the protective film may be separable from the specimen substrate.

In an embodiment, the mother substrate may include glass.

In an embodiment of the disclosure, a testing device for a display apparatus may include a specimen substrate and a plurality of specimen layers disposed on the specimen substrate. The specimen substrate includes a portion of a mother substrate for manufacturing a display apparatus, and the plurality of specimen layers on the specimen substrate includes a portion of layers disposed on the mother substrate for manufacturing the display apparatus.

In an embodiment, the mother substrate may include a first area and a second area surrounding the first area. The first area is an area in which the display apparatus is formed on the mother substrate, and the specimen substrate includes a portion of the second area of the mother substrate.

In an embodiment of the disclosure, a method of manufacturing a display apparatus may include disposing a plurality of layers on a mother substrate, obtaining a specimen by cutting a portion of the mother substrate, and stress-testing the specimen.

In an embodiment, the method of manufacturing a display apparatus may further include separating the plurality of layers disposed on the mother substrate as a whole from the mother substrate.

In an embodiment, the method of manufacturing a display apparatus may further include disposing a reflective layer on the mother substrate or the specimen.

In an embodiment, the method of manufacturing a display apparatus may further include disposing a measurement mark on the specimen.

In an embodiment, the method of manufacturing a display apparatus may further include disposing a protective film on the specimen.

In an embodiment, the protective film may be removed before the stress-testing.

In an embodiment, the method of manufacturing a display apparatus may further include reducing a thickness of the specimen.

In an embodiment, the specimen may be circular in a plan view.

In an embodiment, when cutting the mother substrate, the plurality of layers may be cut together, and the specimen may include a portion of the plurality of layers.

In an embodiment, the mother substrate may include a first area and a second area surrounding the first area, and the first area may include an area in which the display apparatus is formed on the mother substrate, and the specimen may be obtained from the second area.

### BRIEF DESCRIPTION OF THE DRAWINGS

The above and other features and advantages of illustrative embodiments of the disclosure will be more apparent from the following description taken in conjunction with the accompanying drawings, in which:

FIGS. 1, 2, 3, 4, 5A, 5B, and 6 are perspective views showing an embodiment of operations of a method of manufacturing a display apparatus;

FIGS. 7A, 7B, and 7C are schematic plan views of embodiments of test specimens;

FIGS. 8A, 8B, 8C, and 8D are schematic plan views of embodiments of test specimens;

FIGS. 9A and 9B are schematic plan views of embodiments of test specimens;

FIGS. 10A and 10B are schematic perspective views of embodiments of test specimens;

FIGS. 11, 12, and 13 are perspective views showing an embodiment of operations of a method of manufacturing a display apparatus;

FIG. 14 is a plan view of an embodiment of a display panel manufactured by a method of manufacturing a display apparatus; and

FIG. 15 is a cross-sectional view of an embodiment of a display panel manufactured by a method of manufacturing a display apparatus.

### DETAILED DESCRIPTION

As the disclosure allows for various changes and numerous embodiments, illustrative embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, where the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “comprising,” “including,” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

When an illustrative embodiment may be implemented differently, a specific process order may be different from the described order. For example, two consecutively described processes may be performed substantially at the same time or may be performed in an order opposite to the described order.

“A and/or B” is used herein to select only A, select only B, or select both A and B. “At least one of A or B” is used to select only A, select only B, or select both A and B.

In the following embodiments, when a layer, a region, a component, etc. are connected to each other, the layer, the region, and the components may be directly connected to each other and/or the layer, the region, and the components may be indirectly connected to each other with other layers, and other regions and other components may be interposed between the layer, the region, and the components. For example, when a layer, a region, a component, etc. are electrically connected to each other in the specification, the layer, the region, the component, etc. may be directly electrically connected to each other, and/or the layer, the region, the component, etc. may be indirectly electrically connected to each other with other layers, and other regions and other components may be interposed between the layer, the region, and the components.

The x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

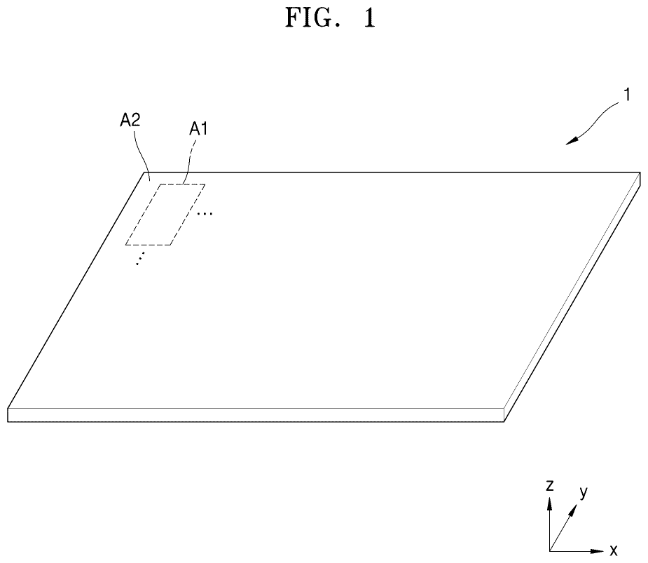

FIGS. 1, 2, 3, 4, 5A, 5B, and 6 are perspective views showing an embodiment of operations of a method of manufacturing a display apparatus.

Referring to FIG. 1, a mother substrate 1 may be prepared. In the disclosure, the mother substrate 1 may be a substrate that provides a base for manufacturing a display apparatus. In an embodiment, the display apparatus may include several layers including inorganic materials, organic materials, and/or metallic materials, and the layers may be disposed on the mother substrate 1. In an embodiment, the mother substrate 1 may include glass.

In an embodiment, the layers of the display apparatus may be disposed on the mother substrate 1 and then separated from the mother substrate 1 and sent to a subsequent process. In this case, the mother substrate 1 may not be included in the display apparatus.

In an embodiment, the layers of the display apparatus may be disposed on the mother substrate 1 and then cut together with the mother substrate 1 to form an individual display apparatus. In this case, it may be understood that a plurality of display apparatuses may be manufactured from one mother substrate 1. In this case, a portion of the mother substrate 1 may be included in the display apparatus.

Hereinafter, for convenience of explanation, a case in which the layers included in the display apparatus are separated from the mother substrate 1 and sent to a subsequent process, that is, a case in which the mother substrate 1 is not included in the display apparatus, is shown and described in detail.

In an embodiment, the mother substrate 1 may have a substantially quadrangular shape, e.g., rectangular shape, in a plan view. In an embodiment, the mother substrate 1 may have a quadrangular shape, e.g., rectangular shape with a long side extending along the x-axis and a short side extending along the y-axis. In an embodiment, the mother substrate 1 may have a quadrangular shape, e.g., rectangular shape with a short side extending along the x-axis and a long side extending along the y-axis. In an embodiment, the mother substrate 1 may have a shape other than a quadrangular shape, e.g., rectangular shape, in a plan view. In an embodiment, the mother substrate 1 may have other shapes such as circular, oval, polygonal, or irregular shapes in a plan view, for example.

In an embodiment, the mother substrate 1 may include a first area A1 and a second area A2. In an embodiment, the first area A1 may have a quadrangular shape, e.g., rectangular shape, in a plan view. In an embodiment, the first area A1 may have a quadrangular shape, e.g., rectangular shape with a short side extending along the x-axis and a long side extending along the y-axis. In an embodiment, a plurality of first areas A1 may be provided. In an embodiment, the plurality of first areas A1 may be spaced apart from each other within the mother substrate 1. In an embodiment, the second area A2 may at least partially surround the first area A1. In an embodiment, the remaining area of the mother substrate 1 excluding the plurality of first areas A1 may be defined as the second area A2. In an embodiment, the first area A1 may define a boundary along which a panel layer is cut to manufacture a display apparatus.

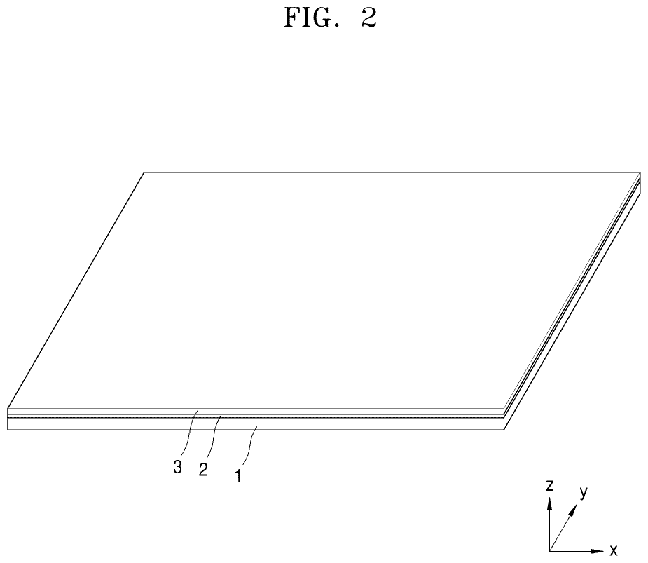

Referring to FIG. 2, a reflective layer 2 and a panel layer 3 may be disposed on the mother substrate 1.

In an embodiment, the reflective layer 2 may be disposed on the upper surface of the mother substrate 1 to cover an entirety of the mother substrate 1. In an embodiment, the reflective layer 2 may be disposed on the mother substrate 1 with a predetermined pattern. The predetermined pattern of the reflective layer 2 will be described in detail later. The reflective layer 2 may include a material that reflects light.

In an embodiment, the panel layer 3 may be disposed on the upper surface of the reflective layer 2 to cover an entirety of the reflective layer 2. In an embodiment, the panel layer 3 may include a plurality of layers. In an embodiment, the panel layer 3 may include light-emitting diodes as display elements and thin-film transistors for driving the light-emitting diodes. In an embodiment, the panel layer 3 may include a plurality of insulating layers in which the light-emitting diodes and the thin-film transistors are disposed. In an embodiment, the panel layer 3 may include a thin-film encapsulation layer to cover and protect the light-emitting diodes. In an embodiment, a portion of the plurality of layers included in the panel layer 3 may not cover an entirety of the reflective layer 2, and may be disposed with a predetermined pattern. In an embodiment, referring to FIG. 1, a portion of the panel layer 3 may be disposed in the first area A1 and may not be disposed in the second area A2. In an embodiment, the light-emitting diode of the panel layer 3 may be disposed only in the first area A1, for example. In an embodiment, the panel layer 3 may include a region that transmits light and a region that does not transmit light. In an embodiment, the panel layer 3 may be a display apparatus in a process of manufacturing or a portion of a display apparatus in a process of manufacturing.

The process of disposing the panel layer 3 may include several processes, such as a deposition process, an inkjet process, and/or an etching process. The panel layer 3 may be disposed in a form similar to an upper surface of the mother substrate 1 and/or the reflective layer 2. In other words, when the upper surface of the mother substrate 1 and/or the reflective layer 2 has a curvature, the curvature may also be in the panel layer 3. This may lead to quality deterioration of the display apparatus. Therefore, during the process of disposing the panel layer 3, the upper surface of the mother substrate 1 and/or the reflective layer 2 need to be maintained flat. In order to maintain the upper surface of the mother substrate 1 and/or the reflective layer 2 flat, the mother substrate 1 and/or the reflective layer 2 may be pulled in a predetermined direction. In an embodiment, the mother substrate 1 and/or the reflective layer 2 may be pulled in the x-axis and/or the y-axis, and the upper surface of the mother substrate 1 and/or the reflective layer 2, e.g., the surface facing in the +z direction, may be flattened, for example. The panel layer 3 may be disposed on the stretched mother substrate 1 and/or the reflective layer 2.

In this case, during the process of pulling the mother substrate 1 to flatten the mother substrate 1, stress may be applied to the mother substrate 1 and deformation (e.g. bending) may occur in the mother substrate 1. The deformation may also occur in the reflective layer 2 and the panel layer 3.

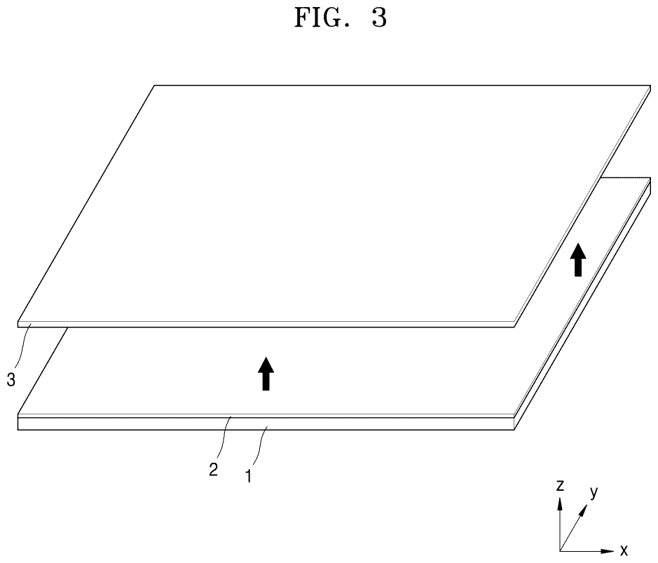

Referring to FIG. 3, the panel layer 3 may be separated from the mother substrate 1 and the reflective layer 2.

As described above, the panel layer 3 may be a display apparatus in a process of manufacturing. Accordingly, the panel layer 3 may be transferred to a subsequent process (e.g., a cutting process), and the next operation of manufacturing the display apparatus may be performed.

As described above, the deformation that occurs in the process of pulling the mother substrate 1 will occur in the panel layer 3, the reflective layer 2, and the mother substrate 1. The deformation may be present even after the panel layer 3 is separated from the mother substrate 1. When the mother substrate 1 and the reflective layer 2 are tested to determine strain in the mother substrate 1, the stress in the mother substrate 1 may be determined, and the strain in the panel layer 3 may be also determined. The testing device (e.g., the test specimen) and a testing method for testing the mother substrate 1 will be described in detail below.

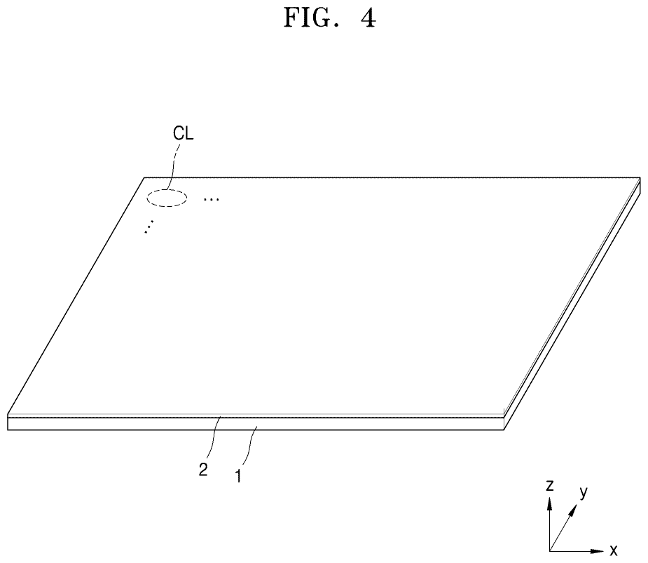

Referring to FIG. 4, a cutting line CL is marked on the mother substrate 1 and the reflective layer 2. The cutting line CL may be an imaginary line marked on the mother substrate 1 and the reflective layer 2 to obtain a specimen. In an embodiment, the cutting line CL may actually be marked on the reflective layer 2. The cutting line CL may define a shape of the specimen. In FIG. 4, the cutting line CL is shown to be substantially a circle, but the disclosure is not limited thereto. The cutting line CL may have other shapes. In an embodiment, a plurality of cutting lines CL may be marked.

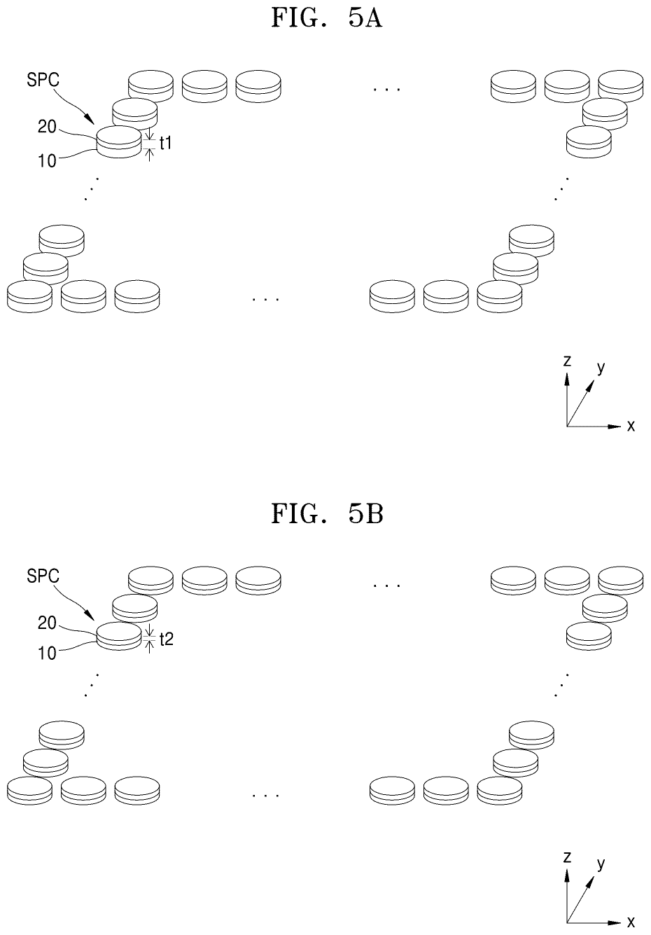

Referring to FIGS. 4, 5A, and 5B, the mother substrate 1 and the reflective layer 2 may be cut along the cutting line CL to obtain a plurality of test specimens SPC.

The test specimen SPC may include a specimen substrate 10 and a reflector 20. In an embodiment, the specimen substrate 10 may be a portion of the mother substrate 1. In an embodiment, the specimen substrate 10 may be a portion of the mother substrate 1 obtained by cutting the mother substrate 1 along the cutting line CL, for example. In an embodiment, the reflector 20 may be a portion of the reflective layer 2. In an embodiment, the reflector 20 may be a portion of the reflective layer 2 obtained by cutting the reflective layer 2 along the cutting line CL, for example. In the disclosure, the reflector 20 included in the test specimen SPC after the cutting may be also referred to as a specimen layer.

When comparing the test specimen SPC shown in FIG. 5A and the test specimen SPC shown in FIG. 5B in embodiments, thicknesses of the specimen substrate 10 in each test specimen SPC may be different. The thickness of the specimen substrate 10 of the test specimen SPC shown in FIG. 5A is defined as a first thickness t1, and the thickness of the specimen substrate 10 of the test specimen SPC shown in FIG. 5B is defined as a second thickness t2. In an embodiment, the first thickness t1 may be greater than the second thickness t2. In other words, the thickness of the specimen substrate 10 of the test specimen SPC shown in FIG. 5B (i.e., the second thickness t2) may be less than a thickness of the mother substrate 1 (i.e., the first thickness t1). In an embodiment, by performing a thinning process on the specimen substrate 10 shown in FIG. 5A, the specimen substrate 10 shown in FIG. 5B may be implemented.

In an embodiment, the mother substrate 1 and the reflective layer 2 may be cut along the cutting line CL to implement the test specimen SPC shown in FIG. 5A. In an embodiment, the mother substrate 1 and the reflective layer 2 may be cut along the cutting line CL, and the specimen substrate 10 may be thinned to obtain the test specimen SPC shown in FIG. 5B. In an embodiment, the mother substrate 1 may be thinned first, and the thinned mother substrate 1 and the reflective layer 2 may be cut to obtain the test specimen SPC shown in FIG. 5B. Hereinafter, for convenience of explanation, the test specimen SPC of FIG. 5A will be shown and described.

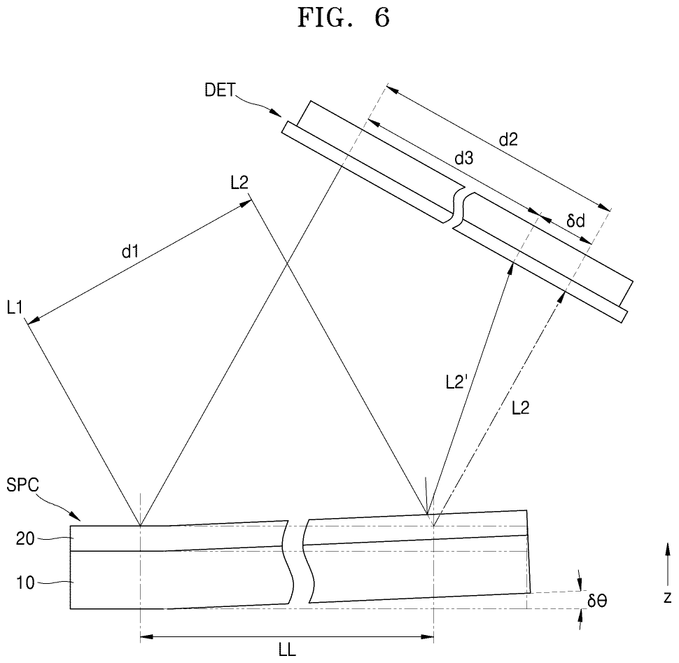

Referring to FIG. 6, stress in the test specimen SPC may be measured.

In order to measure the stress in the test specimen SPC, light may be directed toward the test specimen SPC, the strain in the test specimen SPC may be measured using a path of the light, and the stress in the test specimen may be determined using the measured strain. In an embodiment, the test specimen SPC may be a reflective test specimen, and light may be reflected from a surface of the test specimen SPC, e.g., a surface of the reflector 20.

First, a first light L1 and a second light L2 may be directed toward two points on the test specimen SPC. In an embodiment, the first light L1 and the second light L2 may be directed toward the reflector 20 of the test specimen SPC, for example. A point where the first light L1 is incident and a point where the second light L2 is incident on the test specimen SPC may be spaced apart by a distance LL. The first light L1 and the second light L2 may be spaced apart by a first distance d1.

The first light L1 and the second light L2 may be reflected from the surface of the reflector 20. An angle of incidence and an angle of reflection are the same. A reflection path of the second light L2 when the test specimen SPC is not deformed is shown as a dashed-dotted line L2. The reflection path of the second light L2 when the test specimen SPC is deformed is shown as a solid line L2′. In this case, the test specimen SPC may have deformed in some portions. In an embodiment, the test specimen SPC may be bent approximately in the +z direction by a strain angle δθ, for example.

A detector DET may be disposed on a reflection path of the first light L1 and the second light L2. In an embodiment, the detector DET may be a light detector. Reflected light of the first light L1 and reflected light of the second light L2 when the test specimen SPC is not deformed (i.e., L2) may each reach the detector DET, and arrival points of two light beams may be spaced apart by a second distance d2. The reflected light of the first light L1 and the reflected light of the second light L2 when the test specimen SPC is deformed (i.e., L2′) may each reach the detector DET, and the arrival points of the two light beams may be spaced apart by a third distance d3. A difference between the second distance d2 and the third distance d3 may be defined as a strain distance δd.

Strain in the test specimen SPC may be obtained using the strain angle δθ and/or the strain distance δd. In an embodiment, the strain angle δθ and/or the strain distance δd may be the strain in the test specimen SPC. The specimen substrate 10 may have a known physical property, e.g., a Young's modulus. Based on the known Young's modulus of the specimen substrate 10 and the measured strain of the specimen substrate 10, stress applied to the specimen substrate 10 may be calculated.

The strain in the test specimen SPC obtained through this process may be applied not only to the reflector 20 or the specimen substrate 10, but also to the mother substrate 1 (FIG. 2) and the panel layer 3 (FIG. 2). Therefore, by measuring the strain (and stress) of the test specimen SPC, strain (and stress) in the mother substrate 1 (FIG. 2) and the panel layer 3 (FIG. 2) may be determined. In other words, by measuring the strain (and stress) in the test specimen SPC, strain (and stress) of the display apparatus in the process of manufacturing may be determined. Manufacturing conditions of the display apparatus may be adjusted based on this information.

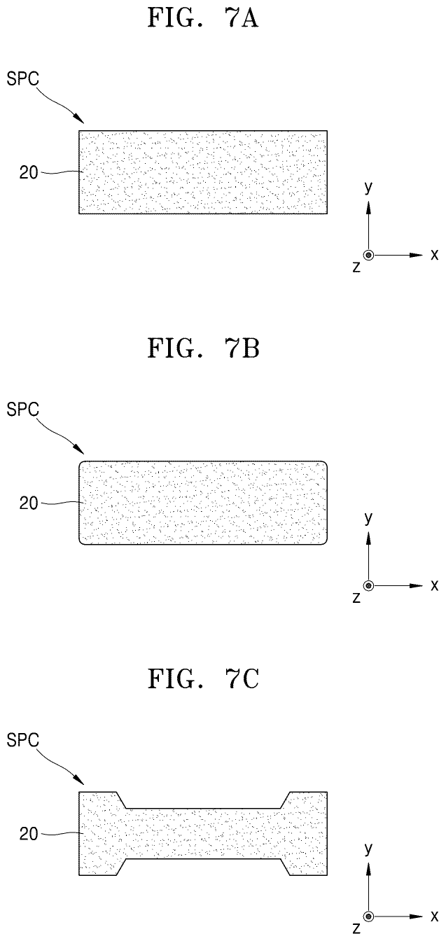

FIGS. 7A, 7B, and 7C are schematic plan views of embodiments of test specimens in some embodiments.

Referring to FIG. 7A, the test specimen SPC may have a quadrangular shape, e.g., rectangular shape, in a plan view. In an embodiment, the test specimen SPC may have a quadrangular shape, e.g., rectangular shape with a long side extending along the x-axis and a short side extending along the y-axis. In an embodiment, the test specimen SPC may have a quadrangular shape, e.g., rectangular shape with a short side extending along the x-axis and a long side extending along the y-axis.

Referring to FIG. 7B, corners of the test specimen SPC may be rounded. In an embodiment, the test specimen SPC may have a long side extending along the x-axis and a short side extending along the y-axis, and the corner(s) where the long side and the short side meet may be rounded. In an embodiment, the test specimen SPC may have a short side extending along the x-axis and a long side extending along the y-axis, and the corner(s) where the long side and the short side meet may be rounded.

Referring to FIG. 7C, the test specimen SPC may have a dog-bone or dumbbell shape. In an embodiment, a portion of the long side extending along the x-axis of the test specimen SPC may be concave along the y-axis, for example. Accordingly, a length of the test specimen SPC along the y-axis may vary along the x-axis. FIG. 7C shows a case in which each edge and corner of the test specimen SPC is angled, but the disclosure is not limited thereto, and at least a portion of each edge and corner may be rounded.

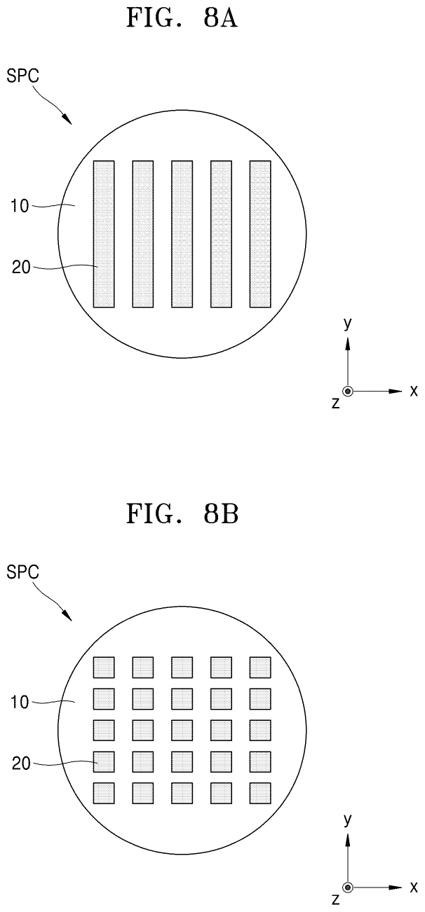

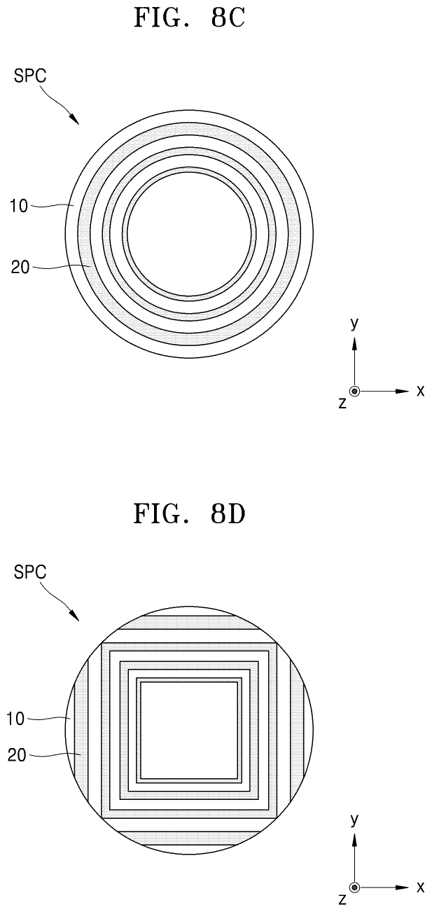

FIGS. 8A, 8B, 8C, and 8D are schematic plan views of embodiments of test specimens. In the embodiments shown in FIGS. 8A to 8D, the reflector 20 of the test specimen SPC may be disposed on the specimen substrate 10, but may not cover an entirety of the specimen substrate 10. The reflector 20 of the test specimen SPC may include a plurality of reflective patterns disposed on the specimen substrate 10.

Referring to FIG. 8A, the reflector 20 may include a plurality of strips extending along the y-axis. The strips may be spaced apart from each other along the x-axis. In an embodiment, the reflector 20 may include a plurality of strips extending along the x-axis, and the strips of the reflector 20 may be spaced apart from each other along the y-axis. FIG. 8A shows an embodiment with five strips, but the disclosure is not necessarily limited to a predetermined number of strips. In an embodiment, as shown in FIG. 8A, the strips of the reflector 20 may be spaced apart from an edge of the specimen substrate 10. In an embodiment, unlike FIG. 8A, a portion of the strips of the reflector 20 may overlap the edge of the specimen substrate 10.

Referring to FIGS. 8A and 6, the first light L1 and the second light L2 may be spaced apart along the x-axis and may be directed toward different strips. In an alternative embodiment, the first light L1 and the second light L2 may be spaced apart along the y-axis and may be directed toward the same strip.

Referring to FIG. 8B, the reflector 20 may include a plurality of islands. The islands may be spaced apart from each other along the x-axis and/or y-axis. In an embodiment, the islands may be approximately square as shown in FIG. 8B. FIG. 8B shows an embodiment with 25 square islands, but the disclosure is not necessarily limited to a predetermined shape or number of islands.

Referring to FIGS. 8B and 6, the first light L1 and the second light L2 may be spaced apart along the x-axis, and may be directed toward different islands. In an alternative embodiment, the first light L1 and the second light L2 may be spaced apart along the y-axis, and may be directed toward different islands. In an alternative embodiment, the first light L1 and the second light L2 may be spaced apart along a diagonal direction of the x-axis and y-axis, and may be directed toward different islands. In an alternative embodiment, the first light L1 and the second light L2 may be spaced apart from each other, and may be directed towards the same island.

Referring to FIG. 8C, the reflector 20 may include a plurality of circular closed loops. In an embodiment, the circular closed loops may be concentric. In an embodiment, thicknesses of the circular closed loops may vary. In an embodiment, the thicknesses of the circular closed loops may each be proportional to a diameter of the circular closed loop. In an embodiment, a thickness of a circular closed loop disposed on the outside (e.g., near the edge of the specimen substrate 10) may be greater than or equal to a thickness of a circular closed loop disposed on the inside (e.g., near the center of the specimen substrate 10), for example. FIG. 8C shows an embodiment with three circular closed loops, but the disclosure is not necessarily limited to a predetermined number of circular closed loops.

Referring to FIG. 8C and 6, the first light L1 and the second light L2 may be spaced apart along the x-axis and may be directed toward different circular closed loops. In an alternative embodiment, the first light L1 and the second light L2 may be spaced apart along the y-axis and may be directed toward different circular closed loops. In an alternative embodiment, the first light L1 and the second light L2 may be spaced apart along a diagonal direction of the x-axis and y-axis, and may be directed toward different circular closed loops.

Referring to FIG. 8D, the reflector 20 may include a plurality of square closed loops or frames. In an embodiment, the frames may be concentric. In an embodiment, thicknesses of the frames may vary. In an embodiment, a thickness of a frame disposed on the outside (e.g. near the edge of the specimen substrate 10) may be greater than or equal to a thickness of a frame disposed on the inside (e.g. near the center of the specimen substrate 10), for example. In an embodiment, a portion of the frame disposed on the outside may overlap an edge of the specimen substrate 10. In an embodiment, only a portion of the frame disposed on the outside may be disposed on the specimen substrate 10.

Referring to FIGS. 8D and 6, the first light L1 and the second light L2 may be spaced apart along the x-axis, and may be directed toward different frames. In an alternative embodiment, the first light L1 and the second light L2 may be spaced apart along the y-axis, and may be directed toward different frames. In an alternative embodiment, the first light L1 and the second light L2 may be spaced apart along a diagonal direction of the x-axis and y-axis, and may be directed toward different frames.

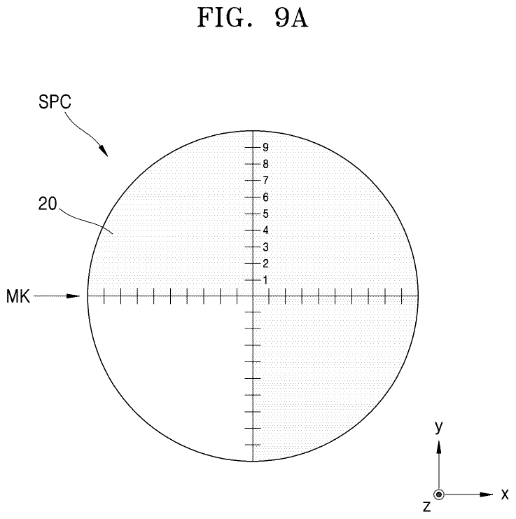

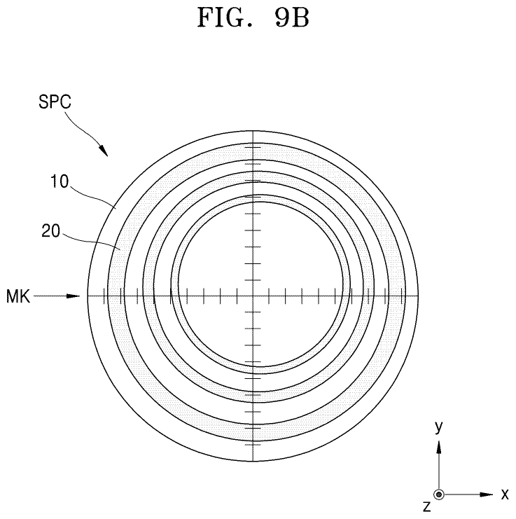

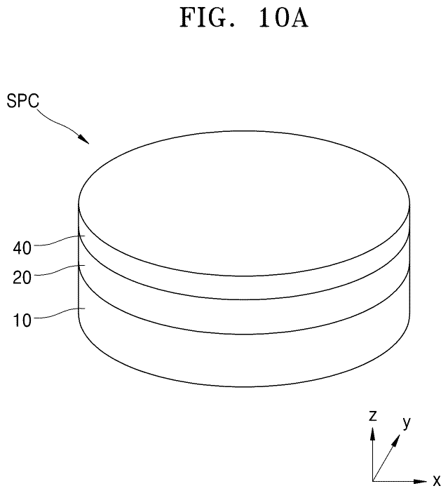

FIGS. 9A and 9B are schematic plan views of embodiments of test specimens.

Referring to FIGS. 9A and 9B, a measurement mark MK may be marked on the test specimen SPC, e.g., on the reflector 20. The measurement mark MK may include an axis and grid lines marked at regular intervals. In an embodiment, as shown in FIG. 9A, the measurement mark MK may include numbers. In an embodiment, as shown in FIG. 9B, the measurement mark MK may not include numbers.

Referring to FIGS. 9A, 9B, and 6, in an embodiment, the distance (i.e. LL) between the incident (or reflection) points of the first light L1 and the second light L2 may be determined based on the measurement mark MK.

Referring to FIGS. 9A, 9B, and 8C, in an embodiment, the reflector 20 including circular closed loops may be distorted and may no longer be concentric as shown in FIG. 9B due to strain in the test specimen SPC. In this case, a direction and a distance in which the circular closed loops of the reflector 20 are distorted may be measured using the measurement mark MK, and the strain in the test specimen may be determined without the need to perform the method (or reflection test) shown in FIG. 6. In this case, the degree of deformation (e.g., strain) may be quickly determined.

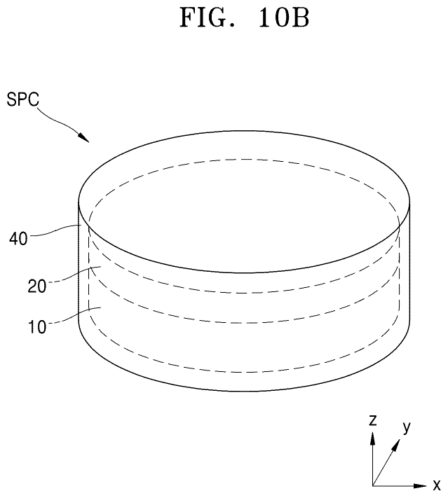

FIGS. 10A and 10B are schematic perspective views of embodiments of test specimens.

Referring to FIGS. 10A and 10B, the test specimen SPC may further include a protective film 40. In the disclosure, the protective film 40 included in the test specimen SPC after the cutting may be also referred to as a specimen layer. In an embodiment, the protective film 40 may be disposed on the reflector 20. In an embodiment, the protective film 40 may include an organic insulating material or an inorganic insulating material. In an embodiment, the protective film 40 may serve to protect the reflector 20 and/or the specimen substrate 10 by preventing oxidation.

In an embodiment, the protective film 40 may be disposed on the upper surface of the reflector 20 and may cover the upper surface of the reflector 20. In an embodiment, the protective film 40 may cover only the upper surface (e.g. surface facing in the +z direction) of the reflector 20 as shown in FIG. 10A. In an embodiment, the protective film 40 may cover the upper and side surfaces of the reflector 20 and the side surfaces of the specimen substrate 10, as shown in FIG. 10B. In an embodiment, the protective film 40 may cover the entirety of the test specimen SPC by also covering the bottom surface (e.g., a surface facing in the −z direction) of the specimen substrate 10.

In an embodiment, the protective film 40 may be removable. In an embodiment, before performing the method (or reflection test) shown in FIG. 6, the protective film 40 may be removed and the upper surface of the reflector 20 may be exposed, for example. In an embodiment, the protective film 40 may be reattached to the reflector 20.

In an embodiment, the protective film 40 may be transparent. In this case, when performing the method (or reflection test) shown in FIG. 6, the protective film 40 may not be removed. Because the protective film 40 may be transparent, light (e.g., the first light L1 and the second light L2) may pass through the protective film 40 and reach the reflector 20.

The embodiments described with reference to FIGS. 7A, 7B, and 7C, the embodiments described with reference to FIGS. 8A, 8B, 8C, and 8D, the embodiments described with reference to FIGS. 9A and 9B, and the embodiments described with reference to FIGS. 10A and 10B may be combined with each other in various ways.

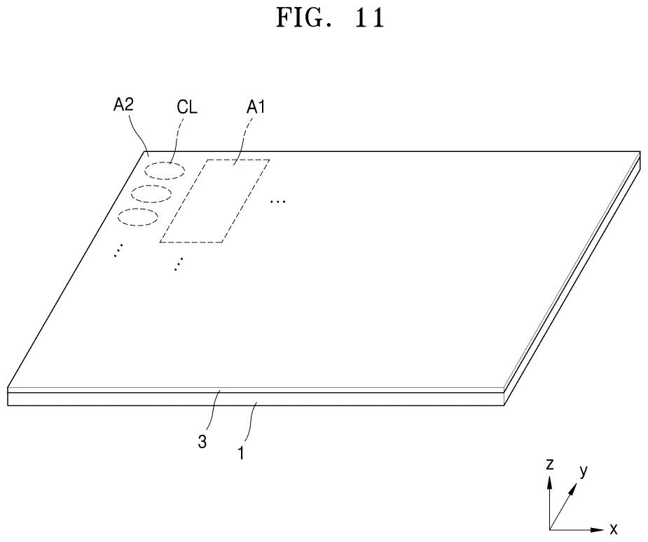

FIGS. 11, 12, and 13 are perspective views showing an embodiment of operations of a method of manufacturing a display apparatus.

Referring to FIG. 11, the panel layer 3 may be placed on the mother substrate 1. In this case, the reflective layer 2 may not be disposed between the mother substrate 1 and the panel layer 3. The mother substrate 1 and the panel layer 3 may each include a first area A1 and a second area A2, similar to the embodiment shown in FIG. 1. Additionally, the mother substrate 1 and the panel layer 3 may each include a cutting line CL, similar to the embodiment shown in FIG. 4. In an embodiment, the cutting line CL may be disposed in the second area A2.

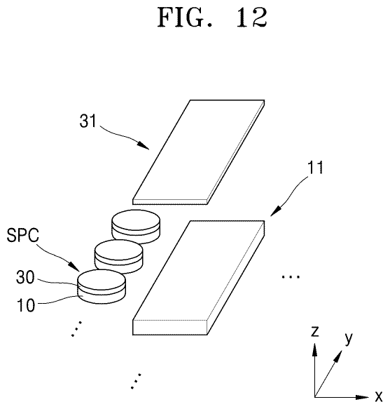

Referring to FIGS. 11 and 12, the mother substrate 1 and the panel layer 3 may be cut along the boundary of the first area A1 and the cutting line CL.

In an embodiment, a portion of the panel layer 3 which has been cut along the boundary of the first area A1 may be a display panel 31. In other words, a portion of the panel layer 3 which has been cut along the boundary of the first area A1 may be a display apparatus in a process of manufacturing. In an embodiment, the display panel 31 may be transferred to a subsequent process and the next operation of manufacturing a display apparatus may be performed on the display panel 31. In an embodiment, a portion of the mother substrate 1 which has been cut along the boundary of the first area A1, i.e., a remaining substrate 11, may be discarded.

In an embodiment, a portion of the mother substrate 1 and the panel layer 3 cut along the cutting line CL may be the test specimen SPC. In an embodiment, a portion of the mother substrate 1 cut along the cutting line CL may be the specimen substrate 10. In an embodiment, a portion of the panel layer 3 cut along the cutting line CL may be a transmission portion 30. In the disclosure, the transmission portion 30 included in the test specimen SPC after the cutting may be also referred to as a specimen layer, for example.

In other words, the mother substrate 1 and the panel layer 3 may each be divided into a first area A1 and a second area A2, and the display panel 31 may be obtained by cutting along the boundary of the first area A1. Additionally, a test specimen SPC may be obtained by cutting along the cutting line CL in an area (i.e. the second area A2) where the display panel 31 is not obtained.

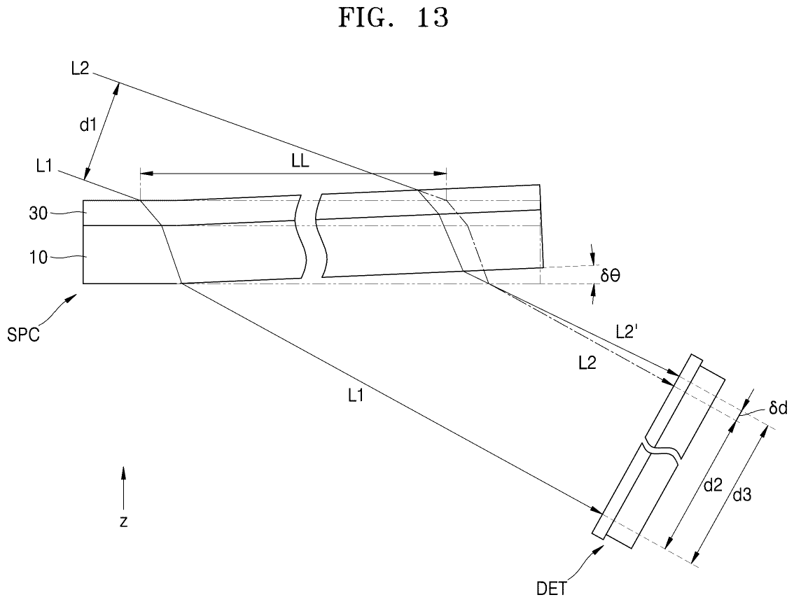

Referring to FIG. 13, stress in the test specimen SPC may be measured.

In order to measure the stress in the test specimen SPC, light may be directed toward the test specimen SPC, strain in the test specimen SPC may be measured using the path of the light, and the stress in the test specimen SPC may be determined using the measured strain. Principles of the stress measurement method shown in FIG. 13 may be similar to principles of the stress measurement method shown in FIG. 6. However, in this embodiment, the test specimen SPC may be a transmission type test specimen, and light may pass through the test specimen SPC. In an embodiment, light may pass through the transmission portion 30 and the specimen substrate 10, for example.

First, a first light L1 and a second light L2 may be directed toward two points of the test specimen SPC. In this case, the first light L1 and the second light L2 may be directed toward the transmission portion 30 of the test specimen SPC. A point where the first light L1 is incident and a point where the second light L2 is incident on the test specimen SPC may be spaced apart by a distance LL. The first light L1 and the second light L2 may be spaced apart by a first distance d1.

For convenience of illustration and explanation, reflected light is not shown. Each of the first light L1 and the second light L2 may be refracted when entering the transmission portion 30 from the surrounding environment (e.g., vacuum). In this case, a refractive index of the transmission portion 30 may be greater than a refractive index of the surrounding environment (e.g., vacuum). Each of the first light L1 and the second light L2 may be refracted when passing through the transmission portion 30 and entering the specimen substrate 10. FIG. 13 shows a case in which the refractive index of the specimen substrate 10 is greater than the refractive index of the transmission portion 30, but the disclosure is not necessarily limited thereto. The first light L1 and the second light L2 may pass through the specimen substrate 10 and enter the surrounding environment (e.g. vacuum). In this case, the refractive index of the specimen substrate 10 may be greater than the refractive index of the surrounding environment (e.g. vacuum).

The reflection path of the second light L2 of the case in which the test specimen SPC is not deformed is shown as a dashed-dotted line L2. The reflection path of the second light L2 of the case in which the test specimen SPC is deformed is shown as a solid line L2′. In this case, the test specimen SPC may deform in some portions. In an embodiment, the test specimen SPC may bend approximately in the +z direction by a strain angle δθ, for example.

A detector DET may be disposed on the path of the first light L1 and the second light L2 after the test specimen SPC. In an embodiment, the detector DET may be a light detector. The transmitted light of the first light L1 and the transmitted light of the second light L2 of the case in which the test specimen SPC is not deformed (i.e., L2) may each reach the detector DET, and the arrival points of the two light beams may be spaced apart by a second distance d2. The transmitted light of the first light L1 and the transmitted light of the second light L2 of the case in which the test specimen SPC is deformed (i.e., L2′) may each reach the detector DET, and the arrival points of the two light beams may be spaced apart by a third distance d3. The difference between the second distance d2 and the third distance d3 may be defined as the strain distance δd.

The strain of the test specimen SPC may be obtained using the strain angle δθ and/or the strain distance δd. In an embodiment, the strain angle δθ and/or the strain distance δd may be the strain in the test specimen SPC. The specimen substrate 10 and/or the transmission portion 30 may have a known physical property, e.g., a Young's modulus. The stress applied to the specimen substrate 10 and/or the transmission portion 30 may be calculated based on the known Young's modulus and measured strain.

The strain in the test specimen SPC obtained through this process may be applied not only to the transmission portion 30 or the specimen substrate 10, but also to the mother substrate 1 (FIG. 11), the panel layer 3 (FIG. 11), and the display panel 31 (FIG. 12). Therefore, by measuring the strain (and stress) of the test specimen SPC, the strain (and stress) of the display panel 31 (FIG. 12) may be determined. In other words, by measuring the strain (and stress) in the test specimen SPC, the strain (and stress) of the display apparatus in a process of manufacturing may be predicted. Manufacturing conditions of the display apparatus may be adjusted based on this information.

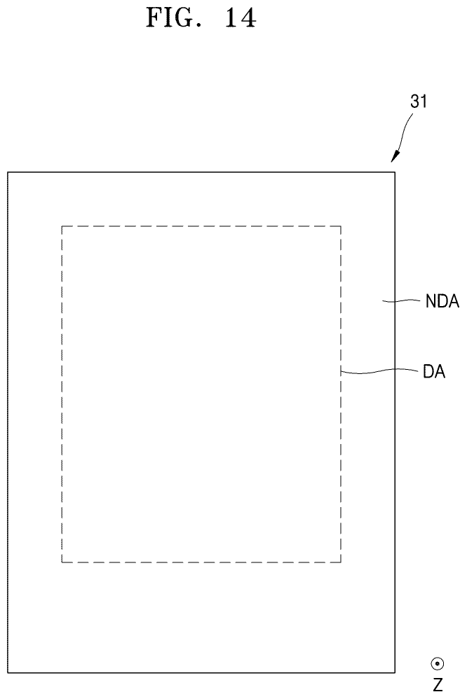

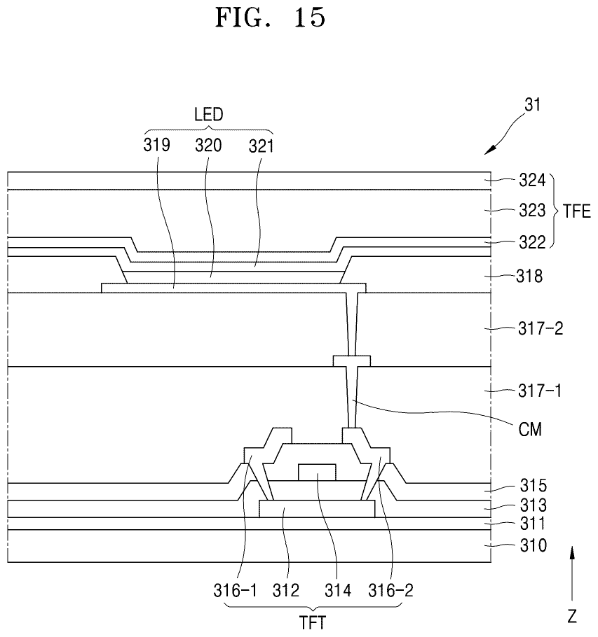

FIG. 14 is a plan view of an embodiment of a display panel manufactured by a method of manufacturing a display apparatus. FIG. 15 is a cross-sectional view of an embodiment of a display panel manufactured by a method of manufacturing a display apparatus.

The display panel 31 of FIGS. 14 and 15 may be an appropriate cut of the panel layer 3 of FIG. 3 or the display panel 31 of FIG. 12, for example. In an embodiment, the display panel 31 may be a display apparatus in a process of manufacturing. In an embodiment, the display panel 31 may be portion of a display apparatus. In an embodiment, the display panel 31 may be the display apparatus itself.

Referring to FIGS. 14 and 15, the display panel 31 may include a display area DA and a non-display area NDA outside the display area DA. A light-emitting diode LED may be disposed in the display area DA, and power wiring (not shown) may be placed in the non-display area NDA. Additionally, a pad portion (not shown) may be disposed in the non-display area. A plurality of deposition material patterns may be arranged in the display area DA.

The substrate 310 may be include polyimide. In an embodiment, the substrate 310 may be flexible, bendable, and/or rollable. A thin-film transistor TFT may be disposed on the substrate 310, a first via layer 317-1 and a second via layer 317-2 may be disposed to cover the thin-film transistor TFT, and the light-emitting diode LED may be disposed thereon.

A buffer layer 311 including an organic compound and/or an inorganic compound may be further disposed on the substrate 310. The buffer layer 311 may include or consist of SiOₓ (x≥1) and/or SiNₓ (x≥1).

An active layer 312 disposed in a predetermined pattern may be disposed on the buffer layer 311, and then, the active layer 312 may be covered by a gate insulating layer 313. The active layer 312 may include a source region and a drain region and may further include a channel region therebetween. The active layer 312 may be formed to include or consist of various materials. In an embodiment, the active layer 312 may include or consist of an inorganic semiconductor material such as amorphous silicon or crystalline silicon. In an embodiment, the active layer 312 may include or consist of an oxide semiconductor. In an embodiment, the active layer 312 may include or consist of an organic semiconductor material.

A gate electrode 314 corresponding to the active layer 312, and an inter-insulating layer 315 covering the gate electrode 314 may be disposed on the gate insulating layer 313. Contact holes are formed in the inter-insulating layer 315 and the gate insulating layer 313, and then, a source electrode 316-1 and a drain electrode 316-2 may be disposed on the inter-insulating layer 315 to be respectively in contact with the source region and the drain region of the active layer 312.

The first via layer 317-1 and the second via layer 317-2 may be disposed on the thin-film transistor TFT, and a pixel electrode 319 of the light-emitting diode LED may be disposed on the second via layer 317-2. The first via layer 317-1 may cover the source electrode 316-1 and the drain electrode 316-2. The second via layer 317-2 may cover the first via layer 317-1. The first via layer 317-1 and the second via layer 317-2 may include an inorganic material and/or an organic material, may be formed as planarization layers such that the upper surfaces thereof are flat regardless of a curvature of a lower layer, or may be curved along the curvature of the lower layer.

A via hole may be formed in the first via layer 317-1, and at least a portion of a contact metal CM may be disposed in the via hole of the first via layer 317-1. A via hole may also be formed in the second via layer 317-2, and a portion of the pixel electrode 319 may be disposed in the via hole of the second via layer 317-2. The pixel electrode 319 contacts the drain electrode 316-2 of the thin-film transistor TFT through the via holes defined in the first via layer 317-1 and the second via layer 317-2. In an embodiment, the contact metal CM may contact the drain electrode 316-2 through the via hole defined in the first via layer 317-1, and the pixel electrode 319 may contact the contact metal CM through the via hole defined in the second via layer 317-2, and thus, may be connected to the drain electrode 316-2, for example.

A pixel defining layer 318 may be disposed on the pixel electrode 319 and the second via layer 317-2. A portion of the pixel defining layer 318 may be opened to expose a portion (e.g., a central portion) of the pixel electrode 319.

An intermediate layer 320 and an opposite electrode 321 may be disposed on the pixel electrode 319. In an embodiment, the opposite electrode 321 may be disposed on the intermediate layer 320 and the pixel defining layer 318. The pixel electrode 319 may function as an anode, and the opposite electrode 321 may function as a cathode. In an embodiment, polarities of the pixel electrode 319 and the opposite electrode 321 may be reversed. The pixel electrode 319 and the opposite electrode 321 are insulated from each other by the intermediate layer 320. The pixel electrode 319 and the opposite electrode 321 apply voltages of different polarities to the intermediate layer 320 to cause an emission layer to emit light.

The intermediate layer 320 may include an emission layer. In another embodiment, the intermediate layer 320 may include an organic emission layer, and may further include at least one of a hole injection layer, a hole transport layer, an electron transport layer, and an electron injection layer in addition to the organic emission layer. The disclosure is not necessarily limited thereto, and the intermediate layer 320 may include an emission layer and may further include various other functional layers (not shown).

One unit pixel includes a plurality of sub-pixels, and the plurality of sub-pixels may emit light of various colors. In an embodiment, the plurality of sub-pixels may include sub-pixels configured to respectively emit red, green, and blue light, or may include sub-pixels (not shown) configured to respectively emit red, green, blue, and white light. The sub-pixel may include one intermediate layer 320.

The thin-film encapsulation layer TFE may be disposed to cover the light-emitting diode LED. The thin-film encapsulation layer TFE may include a plurality of inorganic layers or may include an inorganic layer and an organic layer. In an embodiment, the thin-film encapsulation layer TFE may include a first inorganic encapsulation layer 322, an organic encapsulation layer 323, and a second inorganic encapsulation layer 324, for example. The first inorganic encapsulation layer 322 and/or the second inorganic encapsulation layer 324 may be a single layer or a stacked layer including an oxide material or nitride material. In an embodiment, the first inorganic encapsulation layer 322 and/or the second inorganic encapsulation layer 324 may include at least one of silicon nitride (SiNₓ), aluminum oxide (Al₂O₃), silicon oxide (SiOₓ), and titanium oxide (TiO₂), for example. The organic encapsulation layer 323 may include polymer and be a single layer or a stack layer including at least one of, e.g., polyethylene terephthalate, polyimide, polycarbonate, epoxy, polyethylene, and polyacrylate.

In an embodiment, a testing device for a display includes a specimen substrate obtained from a mother substrate during manufacturing of a display apparatus, i.e., a stress measurement specimen. Because this stress measurement specimen is obtained from a mother substrate used in the manufacture of a display apparatus, the stress measurement specimen may accurately provide physical properties and shape (e.g., curvature) of the display apparatus. In addition, because a plurality of such stress measurement specimens may be obtained from the mother substrate, the stress measurement process may be repeated multiple times using the plurality of stress measurement specimens. Additionally, because there is no need to place a separate element (e.g., a silicon wafer) on the mother substrate, economical effects may also be achieved. In an embodiment, a method of manufacturing a display apparatus including a process of testing the display apparatus by the above-described stress measurement specimen is provided. However, the disclosure is not limited thereto.

While embodiments have been described with reference to the drawing figures, it will be understood by those of ordinary skill in the art that various changes in form and details may be made therein. Therefore, the scope of the disclosure should be defined by the spirit and scope of the following claims.

What is claimed is:

1. A testing device for a display apparatus, the testing device comprising:
a specimen substrate; and
a reflector disposed on the specimen substrate;
wherein the specimen substrate includes a portion of a mother substrate and the display apparatus includes another portion of the mother substrate.

2. The testing device according to claim 1, wherein
the reflector comprises a plurality of reflective patterns spaced apart from each other.

3. The testing device according to claim 2, wherein
the plurality of reflective patterns comprises a plurality of concentric closed loops.

4. The testing device according to claim 1, wherein
a thickness of the specimen substrate is less than a thickness of the mother substrate.

5. The testing device according to claim 1, further comprising:
a measurement mark disposed above the specimen substrate.

6. The testing device according to claim 1, further comprising:
a protective film disposed on the reflector.

7. The testing device according to claim 6, wherein
the protective film is separable from the specimen substrate.

8. The testing device according to claim 1, wherein
the mother substrate includes glass.

9. A testing device for a display apparatus, the testing device comprising:
a specimen substrate; and
a plurality of specimen layers disposed on the specimen substrate;
wherein the specimen substrate includes a portion of a mother substrate and the display apparatus includes another portion of a mother substrate, and
the plurality of specimen layers disposed on the specimen substrate include a portion of layers disposed on the mother substrate and the display apparatus includes another portion of the layers disposed on the mother substrate.

10. The testing device according to claim 9, wherein
the mother substrate includes a first area and a second area surrounding the first area,
the first area is an area in which the display apparatus is formed on the mother substrate, and
the specimen substrate includes a portion of the second area of the mother substrate.

11. A method of manufacturing a display apparatus, the method comprising:
disposing a plurality of layers on a mother substrate;
obtaining a specimen by cutting a portion of the mother substrate; and
stress-testing the specimen.

12. The method according to claim 11, further comprising:
separating the plurality of layers disposed on the mother substrate as a whole from the mother substrate.

13. The method according to claim 12, further comprising:
disposing a reflective layer on the mother substrate or the specimen.

14. The method according to claim 12, further comprising:
disposing a measurement mark on the specimen.

15. The method according to claim 12, further comprising:
disposing a protective film on the specimen.

16. The method according to claim 15, further comprising:
removing the protective film before the stress-testing.

17. The method according to claim 12, further comprising:
reducing a thickness of the specimen.

18. The method according to claim 11, wherein
the specimen is circular in a plan view.

19. The method according to claim 11, wherein
the cutting the mother substrate includes cutting the plurality of layers on the mother substrate together with the mother substrate, and
the specimen includes the plurality of specimen layers.

20. The method according to claim 19, wherein
the mother substrate includes a first area and a second area surrounding the first area,
the first area includes an area in which the display apparatus is formed on the mother substrate, and
the specimen is obtained from the second area.
